(19) United States
(12) Patent Application Publication
(10) Pub. No.: US 2006/0023764 A1
(43) Pub. Date: Feb. 2, 2006

(54) Semiconductor laser and method of manufacturing the same

(76) Inventor: Hironobu Sai, Kyoto-shi (JP)

Correspondence Address: MCDERMOTT WILL & EMERY LLP, 600 13TH STREET, N.W., WASHINGTON, DC, 20005-3096, US

(21) Appl. No.: 11/171,472

(22) Filed: Jul. 1, 2005

(30) Foreign Application Priority Data
Jul. 1, 2004 (JP) P2004-195278

(51) Int. Cl. H01S 5/00

(52) U.S. Cl. 372/46.01

(57) ABSTRACT

In a semiconductor laser according to the present invention, a p-type and n-type semiconductor portion supply positive holes and electrons to a confining layer in a direction perpendicular to a stacking direction of the confining layer, and the p-type and n-type semiconductor portions do not prevent light produced in the confining layer from being emitted by laser oscillation in a stacking direction of intrinsic semiconductor layers. The p-type and n-type semiconductor portion are placed up to a position enough to supply the positive holes and electrons to the confining layer, and supply the positive holes and electrons to the confining layer respectively. As a result, the positive holes and electrons can recombine in the confining layer to produce light.

### CROSS REFERENCE TO RELATED APPLICATION

This application is based upon and claims the benefit of priority from the prior Japanese Patent Application No. P2004-195278, filed on Jul. 1, 2004; the entire contents of which are incorporated herein by reference.

### BACKGROUND OF THE INVENTION

1. Field of the Invention

The present invention relates to a surface-emitting semiconductor laser in which emission efficiency is improved by an electrode arrangement, and to a method of manufacturing the same.

2. Description of the Related Art

Many surface-emitting semiconductor lasers are used, which emit light in the stacking direction of semiconductors. In a known surface-emitting semiconductor laser, a confining layer for confining positive holes and electrons is placed between a layer made of a p-type semiconductor and a layer made of an n-type semiconductor. Positive holes and electrons are moved and supplied to the confining layer from the layer made of the p-type semiconductor and the layer made of the n-type semiconductor, respectively. The positive holes and electrons supplied to the confining layer are confined in the confining layer and recombined to produce light. Lasing multiple reflection layers are formed on opposite sides of the confining layer in the stacking direction, reflect produced light in the stacking direction, and cause laser oscillation.

Thus, in known surface-emitting semiconductor lasers, the direction in which electrons and positive holes are moved is equal to the lasing direction. Accordingly, multiple reflection layers must not only amplify light but also have conductivity for moving the positive holes and electrons, and must contain acceptor or donor impurities. These acceptor and donor impurities cause reductions of the reflectivity of the multiple reflection layers because they absorb light. The reflectivity of the multiple reflection layers cannot be increased to 99.6% or more. The emission efficiency is lowered by the reductions of the reflectivity of multiple reflection layers. Accordingly, in known surface-emitting semiconductor lasers, lasing threshold currents cannot be lowered below 0.5 to 3 mA.

As described above, in known surface-emitting semiconductor lasers, the reflectivity of the multiple reflection layers are lowered because the multiple reflection layers contain the acceptor and donor impurities, and the lasing threshold currents are large.

### BRIEF SUMMARY OF THE INVENTION

The present invention has been made considering the problems, and its object is to provide a semiconductor laser in which the emission efficiency can be improved and in which the lasing threshold current can be lowered, and to provide a method of manufacturing the same.

A first aspect of the present invention is summarized as a semiconductor laser including: a confining layer configured to confine positive holes and electrons; an upper intrinsic semiconductor layer made of an intrinsic semiconductor which is placed on one side of the confining layer in a stacking direction; an upper multiple reflection layer made of intrinsic semiconductors which are placed in a portion of the upper intrinsic semiconductor layer in parallel with a plane of the confining layer and is configured to reflect part of light produced in the confining layer to cause laser oscillation; a lower intrinsic semiconductor layer made of an intrinsic semiconductor which is placed on another side of the confining layer in the stacking direction; a lower multiple reflection layer made of intrinsic semiconductors which are placed in a portion of the lower intrinsic semiconductor layer in parallel with the plane of the confining layer and is configured to reflect part of light produced in the confining layer to cause laser oscillation; a p-type semiconductor portion formed by distributing acceptor impurities in a portion of the upper intrinsic semiconductor layer and/or the lower intrinsic semiconductor layer; and an n-type semiconductor portion placed to be separated from the p-type semiconductor portion in a direction perpendicular to a stacking direction of the upper and lower intrinsic semiconductor layers, the n-type semiconductor portion being formed by distributing donor impurities in a portion of the upper intrinsic semiconductor layer and/or the lower intrinsic semiconductor layer. And positive holes supplied from the p-type semiconductor portion and electrons supplied from the n-type semiconductor portion recombine in the confining layer to produce light.

In the first aspect, the p-type and n-type semiconductor portions can be placed at positions where the p-type and n-type semiconductor portions do not prevent the light produced in the confining layer from being emitted by laser oscillation in the stacking direction of the upper and lower intrinsic semiconductor layer.

In the first aspect, adjacent portions of the p-type and n-type semiconductor portions can have shapes with which current confinement is achieved in the confining layer.

In the first aspect, projected shapes of adjacent portions of the p-type and n-type semiconductor portions on the confining layer can have convex shapes having vertices in the adjacent portions.

In the first aspect, the p-type and n-type semiconductor portions can be formed in any one of the upper and lower intrinsic semiconductor layers to face each other in a direction approximately perpendicular to the stacking direction of the upper and lower intrinsic semiconductor layers.

In the first aspect, the p-type and n-type semiconductor portions can be placed so that the highest portions of density distributions of the acceptor and donor impurities of the p-type and n-type semiconductor portions are placed with the confining layer interposed therebetween.

In the first aspect, the p-type semiconductor portion and/or the n-type semiconductor portion can be formed from at least one of electrode placement portions from which currents are respectively supplied to the p-type and n-type semiconductor portions, to a portion in which the positive holes and electrons cause the tunnel effect to the confining layer.

In the first aspect, the p-type semiconductor portion and/or the n-type semiconductor portion can be formed from at least one of electrode placement portions from which currents are respectively supplied to the p-type and n-type semiconductor portions, to a portion at a distance of not more than 200 nm from the confining layer.

In the first aspect, the p-type semiconductor portion and/or the n-type semiconductor portion can be distributed from at least one of electrode placement portions from which currents are respectively supplied to the p-type and n-type semiconductor portions, to a portion reaching the confining layer.

In the first aspect, at least one of the p-type and n-type semiconductor portions can be formed across the upper and lower intrinsic semiconductor layers.

In the first aspect, the confining layer can have a double-hetero structure interposed between layers having large energy gaps.

In the first aspect, the confining layer can have a quantum well structure.

In the first aspect, the confining layer can have a narrowed shape in at least part of a portion which connects projected portions of the p-type and n-type semiconductor portions on the confining layer.

In the first aspect, the confining layer can have a stripe structure which connects adjacent portions of projected portions of the p-type and n-type semiconductor portions on the confining layer, in at least the adjacent portions.

In the first aspect, the semiconductor laser can further include a lens electrode in a portion close to at least part of the upper intrinsic semiconductor layer and/or the lower intrinsic semiconductor layer, the lens electrode limiting movement of the positive holes and electrons using an electric field.

In the first aspect, each of the upper and lower multiple reflection layers can have at least 10 pairs of reflection layers.

In the first aspect, the upper and lower multiple reflection layers can be formed of any one of AlGaAs, AlGaN, AlGaInN, AlGaInAs, ZnCdSeS, ZnMgSSe, and ZnSSe materials.

In the first aspect, a distance between the upper and lower multiple reflection layers can be in a range from one wavelength to 30 wavelengths in terms of a lasing wavelength.

A second aspect of the present invention is summarized as a method of manufacturing a semiconductor laser, including: depositing a lower intrinsic semiconductor layer made of an intrinsic semiconductor which includes a lower multiple reflection layer being made of intrinsic semiconductors and reflecting light to cause laser oscillation; forming a confining layer on the lower intrinsic semiconductor layer deposited in the step of depositing the lower intrinsic semiconductor layer, the confining layer confining positive holes and electrons; depositing an upper intrinsic semiconductor layer made of an intrinsic semiconductor on the confining layer formed in the step of forming the confining layer, the upper intrinsic semiconductor layer including an upper multiple reflection layer being made of intrinsic semiconductors and reflecting light to cause laser oscillation; forming electrode placement portions by selectively removing, by dry etching, part of the upper intrinsic semiconductor layer deposited in the step of depositing the upper intrinsic semiconductor layer in accordance with shapes of a p-side electrode and an n-side electrode to be formed; placing a p-type electrode material containing acceptor impurities in one electrode placement portion formed in the step of forming the electrode placement portions, and placing an n-type electrode material containing donor impurities in another electrode placement portion formed in the step of forming the electrode placement portions; and annealing the p-type and n-type electrode materials placed in the step of placing the p-type and n-type electrode materials, and at least part of the upper intrinsic third second aspect of the present invention is summarized as a method of manufacturing a semiconductor laser, including: depositing a lower intrinsic semiconductor layer made of an intrinsic semiconductor which includes a lower multiple reflection layer being made of intrinsic semiconductors and reflecting light to cause laser oscillation; forming a confining layer on the lower intrinsic semiconductor layer deposited in the step of depositing the lower intrinsic semiconductor layer, the confining layer confining positive holes and electrons; depositing an upper intrinsic semiconductor layer made of an intrinsic semiconductor on the confining layer formed in the step of forming the confining layer, the upper intrinsic semiconductor layer including an upper multiple reflection layer being made of intrinsic semiconductors and reflecting light to cause laser oscillation; forming electrode placement portions by selectively removing, by dry etching, part of the lower intrinsic semiconductor layer deposited in the step of depositing the lower intrinsic semiconductor layer, the confining layer formed in the step of forming the confining layer, and the upper intrinsic semiconductor layer deposited in the step of depositing the upper intrinsic semiconductor layer in accordance with a shape of any one of a p-side electrode and an n-side electrode to be formed, and by selectively removing, by dry etching, the upper intrinsic semiconductor layer deposited in the step of depositing the upper intrinsic semiconductor layer in accordance with a shape of another of the p-side and n-side electrodes to be formed; placing a p-type electrode material containing acceptor impurities in one electrode placement portion formed in the step of forming the electrode placement portions, and placing an n-type electrode material containing donor impurities in other electrode placement portion formed in the step of forming the electrode placement portions; and annealing the p-type and n-type electrode materials placed in the step of placing the electrode materials, and at least part of the lower intrinsic semiconductor layer.

### BRIEF DESCRIPTION OF THE SEVERAL VIEWS OF THE DRAWINGS

FIGS. 1(a) and 1(b) are views for explaining the structure of a semiconductor laser according to one embodiment of the present invention.

FIG. 2 is a view for explaining a cross-sectional structure of the semiconductor laser according to the embodiment of the present invention.

FIG. 3 is a view for explaining the shape of a confining layer of the semiconductor laser according to the embodiment of the present invention as seen from the exit surface of laser light.

FIG. 4 is a cross-sectional view of the shape shown in FIG. 3, which is taken along the B-B′ line.

FIG. 5 is a view for explaining the structure of the confining layer as seen from the exit surface of laser light.

FIG. 6 is a cross-sectional view of the structure shown in FIG. 5, which is taken along the B-B′ line.

FIGS. 7(a) and 7(b) are views for explaining an example in which lens electrodes are arranged.

FIG. 8 is a view for explaining the step of depositing each of semiconductor layers on a substrate.

FIGS. 9(a) and 9(b) are views for explaining an etched shape as seen from the exit surface of laser light.

FIGS. 10(a) and 10(b) are views for explaining an example of the formation of a p-type electrode material and an n-type electrode material.

FIGS. 11(a) and 11(b) are views for explaining the states of acceptor and donor impurities distributed by annealing.

FIG. 12 is a view for explaining a cross-sectional structure of a semiconductor laser according to one embodiment of the present invention.

FIG. 13 is a view for explaining a cross-sectional structure of the semiconductor laser after etching.

### DETAILED DESCRIPTION OF THE INVENTION

Hereinafter, embodiments of the present invention will be described in detail with reference to the drawings. Note that the present invention is not limited to the embodiments described below.

### Embodiment 1

A semiconductor laser of embodiment 1 of the present invention is a semiconductor laser in which p-type and n-type semiconductor portions placed in portions of layers made of intrinsic semiconductors supply electrons and positive holes to a confining layer in directions perpendicular to the stacking direction of the confining layer and in which the p-type and n-type semiconductor portions are provided at positions where they do not prevent light produced in the confining layer from being emitted by laser oscillation in the stacking direction of the intrinsic semiconductor layers. Note that an intrinsic semiconductor here is not limited to one in which atoms can share electrons in the outermost shells thereof.

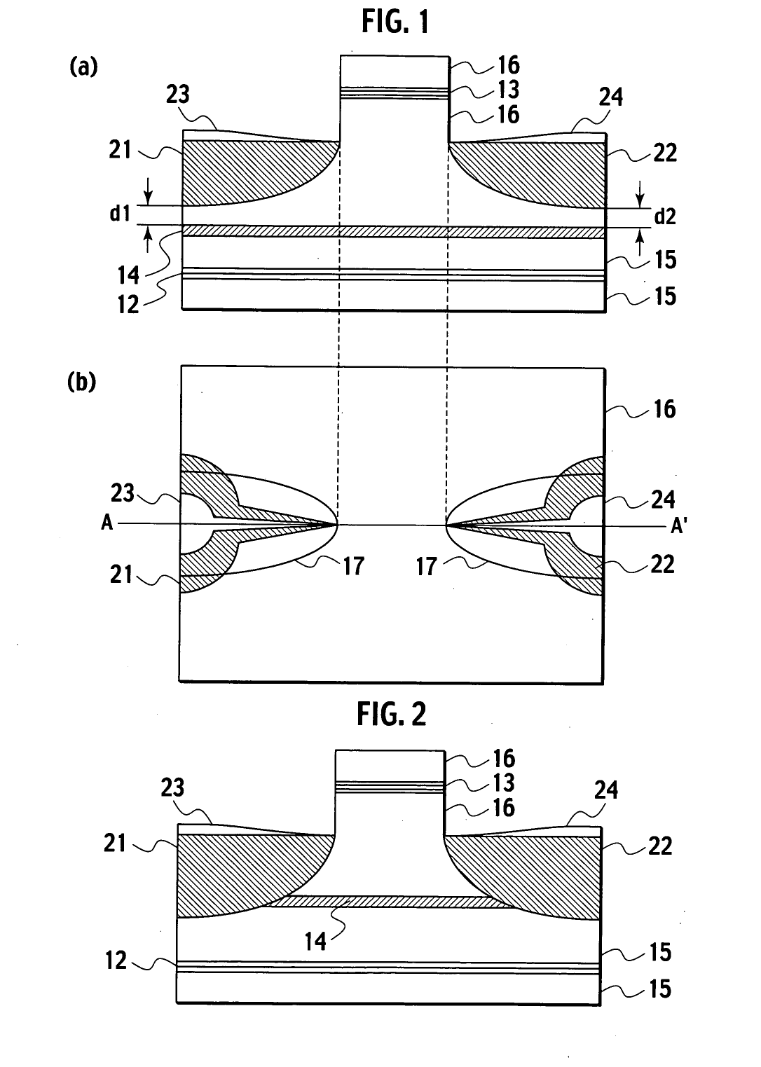

The semiconductor laser of the embodiment 1 of the present invention will be described using FIGS. 1(a) and 1(b). FIG. 1(b) is a view for explaining the structure of the semiconductor laser according to the present invention as seen from the exit surface of laser light.

FIG. 1(a) is a cross-sectional view taken along the A-A′ line in FIG. 1(b). In FIGS. 1(a) and 1(b), “12” is a lower multiple reflection layer, “13” is an upper multiple reflection layer, “14” is a confining layer, “15” is a lower intrinsic semiconductor layer, “16” is an upper intrinsic semiconductor layer, “17” is an electrode placement portion, “21” is a p-type semiconductor portion, “22” is an n-type semiconductor portion, “23” is a p-side electrode, “24” is an n-side electrode, “d1” is the distance between the confining layer 14 and the portion of the p-type semiconductor portion 21 which is closest to the confining layer 14, and “d2” is the distance between the confining layer 14 and the portion of the n-type semiconductor portion 22 which is the closest to the confining layer 14.

The semiconductor laser according to this embodiment includes the lower multiple reflection layer 12, the upper multiple reflection layer 13, the upper intrinsic semiconductor layer 16, the lower intrinsic semiconductor layer 15, the confining layer 14, the p-type semiconductor portion 21, the n-type semiconductor portion 22, the p-side electrode 23, and the n-side electrode 24. In the semiconductor laser, the lower intrinsic semiconductor layer 15, the lower multiple reflection layer 12, the lower intrinsic semiconductor layer 15, the confining layer 14, the upper intrinsic semiconductor layer 16, the upper multiple reflection layer 13, and the upper intrinsic semiconductor layer 16 are stacked in this order.

As shown in FIG. 1(b), the upper intrinsic semiconductor layer 16 is partially etched in accordance with the shapes of the p-side and n-side electrodes 23 and 24 at the positions where the p-side and n-side electrodes 23 and 24 are placed, whereby the electrode placement portions 17 are formed. As shown in FIG. 1(a), the etch depths of the electrode placement portions 17 reach an intermediate portion of the upper intrinsic semiconductor layer 16 including the upper multiple reflection layer 13.

The p-side and n-side electrodes 23 and 24 are arranged in the electrode placement portions 17. As shown in FIG. 1(b) the p-type and n-type semiconductor portions 21 and 22 are formed in the upper intrinsic semiconductor layer 16 with the p-side and n-side electrodes 23 and 24 at approximately central portions thereof.

Incidentally, the p-type and n-type semiconductor portions 21 and 22 are preferably formed at positions where they do not prevent light produced inside the confining layer 14 from being emitted in the stacking direction of the upper and lower intrinsic semiconductor layers 16 and 15.

As shown in FIGS. 1(a) and 1(b), the p-type and n-type semiconductor portions 21 and 22 are formed to be separated in a direction approximately perpendicular to the stacking direction of each semiconductor layer. The distance between the p-type and n-type semiconductor portions 21 and 22 is not limited. For example, a distance of approximately 2 μm may be provided therebetween. Lased light is emitted through this portion. Thus, the lasing light can be prevented from being absorbed by acceptor and donor impurities. Accordingly, a semiconductor laser can be provided in which the emission efficiency can be further improved and in which the lasing threshold can be further lowered.

Moreover, the p-type semiconductor portion 21 and/or the n-type semiconductor portion 22 is preferably distributed from the corresponding electrode placement portions (or portion) 17 from which currents are respectively supplied to the p-type and n-type semiconductor portions 21 and 22, to a portion at a distance of not more than 200 nm from the confining layer 14, respectively. In this case, the distance d1 and/or the distance d2 shown in FIG. 1(a) is not more than 200 nm. Further, the acceptor impurities and/or the donor impurities in the example 1 shown in FIG. 1(a) is distributed from the corresponding electrode placement portions (or portion) 17 from which currents are respectively supplied to the p-type and n-type semiconductor portions 21 and 22, to a portion from which the positive holes and electrons cause the tunnel effect to the confining layer 14, respectively.

By the distance d1 and/or the distance d2 being not more than 200 nm, the positive holes and electrons can be supplied from the p-type and n-type semiconductor portions 21 and 22 to the confining layer 14 by the tunneling effect, and the distribution of the acceptor and donor impurities can be prevented from widening. Thus, unnecessary dispersion of impurities can be prevented, and therefore it is possible to prevent reductions of the reflectivity of the lower and upper multiple reflection layers 12 and 13. Accordingly, a semiconductor laser can be provided in which the emission efficiency can be further improved and in which the lasing threshold can be further lowered.

The lower and upper multiple reflection layers 12 and 13 are configured to reflect at least part of light produced in the confining layer 14 and to cause laser oscillation. Each of the lower and upper multiple reflection layers 12 and 13 is a multiple reflection layer in which a plurality of pairs of reflection layers that reflect light are stacked. A Bragg reflection type (DBR) may be adopted. The lower and upper multiple reflection layers 12 and 13 are placed on opposite sides of the confining layer 14, respectively. The lower and upper multiple reflection layers 12 and 13 are deposited in portions of the lower and upper intrinsic semiconductor layers 16 and 15, respectively, and constitute an optical resonator with portions of the confining layer 14 and the upper and lower intrinsic semiconductor layers 16 and 15 interposed therebetween.

Each of the lower and upper multiple reflection layers 12 and 13 preferably has at least 10 pairs of reflection layers which reflect light produced by recombination radiation in the confining layer 14. With at least 10 pairs of reflection layers constituting each of the lower and upper multiple reflection layers 12 and 13, lasing efficiency can be improved. Accordingly, a semiconductor laser can be provided in which the emission efficiency can be further improved and in which the lasing threshold can be further lowered.

Each of the upper and lower multiple reflection layers 13 and 12 is preferably made of pairs of GaAs and AlGaAs. With reflection layers made of GaAs/AlGaAs, the reflectivity of light produced in the confining layer can be improved. Accordingly, a semiconductor laser can be provided in which the emission efficiency can be further improved and in which the lasing threshold can be further lowered.

Incidentally, the thickness of each of GaAs and AlGaAs may be L/{4×Re(n)} (where “L” is a wavelength, “n” is a refractive index, and “Re” is a real part). Reflection layers of GaAs and AlGaAs having thicknesses of “L/{4×Re(n)}” are alternately stacked.

The upper and lower intrinsic semiconductor layers 16 and 15 are made of intrinsic semiconductors. Incidentally, they are not limited to intrinsic semiconductors. It is essential only that the carrier densities thereof, i.e., the densities of acceptor and donor impurities therein, are lower than those of the p-type and n-type semiconductor portions 21 and 22. Materials for the upper and lower intrinsic semiconductor layers 16 and 15 include group IV semiconductors. The group IV semiconductors include Ge, C, Sn, and Pb in addition to Si.

The p-type semiconductor portion 21 is part of the upper intrinsic semiconductor layer 16 in which the acceptor impurities are distributed. By a voltage applied from the p-side electrode 23, the positive holes are supplied to the confining layer 14. The n-type semiconductor portion 22 is part of the upper intrinsic semiconductor layer 16 in which the donor impurities are distributed. By a voltage applied from the n-side electrode 24, the electrons are supplied to the confining layer 14. In the p-type and n-type semiconductor portions 21 and 22, it is acceptable that the densities of the acceptor and donor impurities are approximately 10 times those in the upper and lower intrinsic semiconductor layers 16 and 15.

The confining layer 14 is configured to confine the positive holes and electrons. The confining layer 14 causes the supplied positive holes and electrons to recombine and produce light. Materials forming the confining layer 14 are not limited. For example, GaAs/AlGaAs semiconductors may be used. Alternatively, GaAs/InGaAs or InP/InGaAs semiconductors may be also used.

The p-side and n-side electrodes 23 and 24 are configured to apply voltages to the p-type and n-type semiconductor portions 21 and 22, respectively. Materials usable for these electrodes include Au/Ti.

The operation of the semiconductor laser according to the present invention will be described using FIGS. 1(a) and 1(b). Voltages are applied to the p-side and n-side electrodes 23 and 24. The positive holes contained in the acceptor impurities distributed in the p-type semiconductor portion 21 are led to the confining layer 14. The electrons contained in the donor impurities distributed in the n-type semiconductor portion 22 are also led to the confining layer 14.

The positive holes led to the confining layer 14 move in the confining layer 14 in the direction of the n-type semiconductor portion 22. On the other hand, the electrons led to the confining layer 14 move in the confining layer 14 in the direction of the p-type semiconductor portion 21. Thus, the positive holes and electrons supplied to the confining layer 14 recombine to produce light while they move in the confining layer 14 between the p-type and n-type semiconductor portions 21 and 22. The light produced by recombination in the confining layer 14 is reflected by the lower and upper multiple reflection layers 12 and 13 respectively included in the lower and upper intrinsic semiconductor layers 15 and 16 between which the confining layer 14 is interposed, thus causing laser oscillation. This makes it possible to emit laser light through the upper multiple reflection layer 13 in the stacking direction of the lower and upper intrinsic semiconductor layers 15 and 16.

As described above, the semiconductor laser according to the present invention can lase without containing acceptor or donor impurities in the lower and upper multiple reflection layers 12 and 13. This makes it possible to improve the reflectivity of the lower and upper multiple reflection layers 12 and 13. For example, it is also possible to use reflection layers having reflectivity of 99.98%. Accordingly, a semiconductor laser can be provided in which the emission efficiency can be improved and in which the lasing threshold can be lowered.

Incidentally, the projected shapes of the p-type and n-type semiconductor portions 21 and 22 on the confining layer 14 are preferably convex shapes having vertices in adjacent portions thereof, respectively. That is, as shown in FIG. 1(b), adjacent portions of the p-type and/or n-type semiconductor portions 21 and 22 preferably have shapes with which current confinement is achieved in the confining layer 14. Thus, the current confinement can be achieved in the confining layer 14 by the projected shapes of the p-type and n-type semiconductor portions 21 and 22 on the confining layer 14 being convex shapes having acute vertices in portions thereof which are closest to each other. This makes it possible to improve the efficiency with which the positive holes and electrons are recombined to produce light. Accordingly, a semiconductor laser can be provided in which the emission efficiency can be further improved and in which the lasing threshold can be further lowered.

Moreover, the p-type and n-type semiconductor portions 21 and 22 are preferably formed to face each other in a direction approximately perpendicular to the stacking direction of the lower and upper intrinsic semiconductor layers 15 and 16. That is, as shown in FIG. 1(a), the p-type and n-type semiconductor portions 21 and 22 are preferably formed by distributing the acceptor and donor impurities so that the electrode placement portions 17 in which a lasing portion is etched to approximately the same depths are at approximately central portions thereof. Thus, since the etch depths for forming the electrode placement portions 17 of the p-side and n-side electrodes may be equal, an etching process becomes easy. Accordingly, a semiconductor laser can be provided which is easily manufactured, in which the emission efficiency can be improved, and in which the lasing threshold can be lowered.

Further, the confining layer 14 preferably has a double-hetero structure in which the confining layer 14 has an energy gap smaller than those of the two layers adjacent to the confining layer 14 in the stacking direction on opposite sides thereof, i.e., the lower and upper intrinsic semiconductor layers 15 and 16. If the energy gap of the confining layer 14 is smaller than those of the materials of the upper and lower intrinsic semiconductor layers 16 and 15, the positive holes and electrons supplied to the confining layer 14 can be confined in the confining layer. This makes it possible to efficiently confine the positive holes and electrons in the confining layer. In the present invention, since the confining layer 14 is interposed between the upper and lower intrinsic semiconductor layers 16 and 15, a confining effect can be made large. Accordingly, a semiconductor laser can be provided in which the emission efficiency can be improved and in which the lasing threshold can be lowered.

Moreover, the confining layer 14 preferably includes a quantum well structure having the effect of confining the positive holes and electrons. The quantum well structure is not limited. The confining layer may have a thickness (on the order of 10 nm) equal to or less than approximately the de Broglie wavelengths of an electron and a positive hole to confine the electrons and positive holes in a two-dimensional plane. With such a structure, the positive holes and electrons can be confined in the confining layer 14.

The confining layer 14 may have a quantum wire structure in which the electrons and positive holes are confined on a straight line. With the quantum wire structure, the movement of the positive holes and electrons can be limited. The confining layer 14 may have a quantum dot structure in which the electrons and positive holes are three-dimensionally confined. With the quantum dot structure, the effect of confining the positive holes and electrons in the confining layer 14 can be made large. Further, the confining layer 14 may have a multiple quantum well structure in which two or more quantum well structures overlap. With the multiple quantum well structure, more positive holes and electrons can be confined in the confining layer 14.

The quantum well structure is not limited. As an example of the quantum well structure, 2.5 atomic layers of InAs may be grown on a smoothed buffer layer of GaAs. This makes it possible to form island-shaped quantum dots which are approximately several atomic layers in thickness and approximately several hundreds of atomic layers in diameter and in which atoms are agglomerated, because of the difference between the lattice constants of the InAs and the GaAs buffer layers.

Thus, the effect of confining the positive holes and electrons in the confining layer 14 can be improved by the confining layer 14 including the quantum well structure. Accordingly, a semiconductor laser can be provided in which the emission efficiency can be further improved and in which the lasing threshold can be further lowered.

Furthermore, the confining layer 14 preferably has a narrowed shape in at least part of a portion which connects the projected portions of the p-type and n-type semiconductor portions 21 and 22 on the confining layer. That is, the confining layer preferably has a mesa structure.

One example of this confining layer 14 is shown in FIGS. 3 and 4. FIG. 3 is a view for explaining the shape of the confining layer 14 of the semiconductor layer according to the present invention as seen from the exit surface of laser light. As in FIGS. 1(a) and 1(b), “15” is the lower intrinsic semiconductor layer, “16” is the upper intrinsic semiconductor layer, and “14” is the confining layer. FIG. 4 is a cross-sectional view taken along the B-B′ line shown in FIG. 3. As shown in FIG. 3, a portion near the center which connects the p-type and n-type semiconductor portions 21 and 22 has a narrowed shape.

In this example, a narrowed shape is formed by removing only the confining layer by etching or the like, and the upper intrinsic semiconductor layer 16 is further deposited on the confining layer 14. Because of this narrowed shape, as shown in FIG. 4, the periphery thereof is surrounded by the intrinsic semiconductors constituting the upper and lower intrinsic semiconductor layers 16 and 15. Accordingly, a portion in which the positive holes and electrons can exist can be further limited to increase the efficiency with which the positive holes and electrons are recombined to produce light. Thus, a semiconductor laser can be provided in which the emission efficiency can be further improved and in which the lasing threshold can be further lowered.

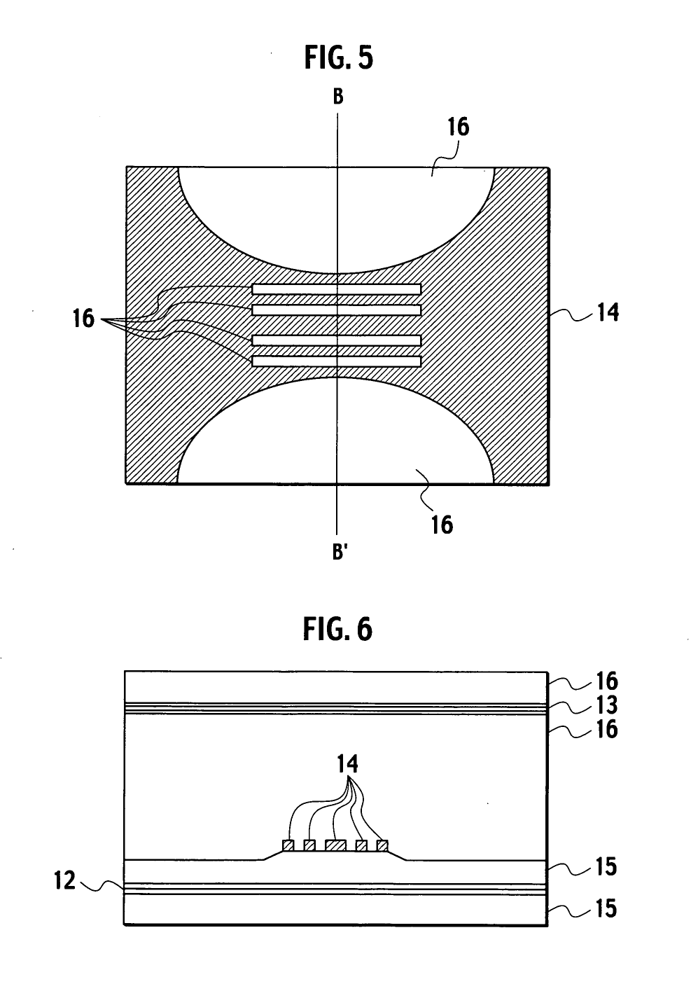

Moreover, the confining layer 14 preferably has a striped structure which connects adjacent portions of the projected portions of the p-type and n-type semiconductor portions 21 and 22 on the confining layer 14. An example of the present invention is shown in FIGS. 5 and 6. FIG. 5 is a view for explaining the structure of the confining layer as seen from the exit surface of laser light. FIG. 6 is a cross-sectional view taken along the B-B′ line shown in FIG. 5.

As shown in FIG. 5, a striped structure which connects the p-type and n-type semiconductor portions 21 and 22 is combined with the current confining structure described in the aforementioned FIGS. 3 and 4. As shown in FIG. 6, the confining layer 14 preferably has a buried hetero structure in which the confining layer 14 is processed to have a striped shape and in which the surrounding region is filled with a high-resistance semiconductor crystal. This makes it possible to further narrow the portion in which the positive holes and electrons move. Accordingly, the efficiency with which the positive holes and electrodes are recombined to produce light can be increased. Thus, a semiconductor laser can be provided in which the emission efficiency can be further improved and in which the lasing threshold can be further lowered.

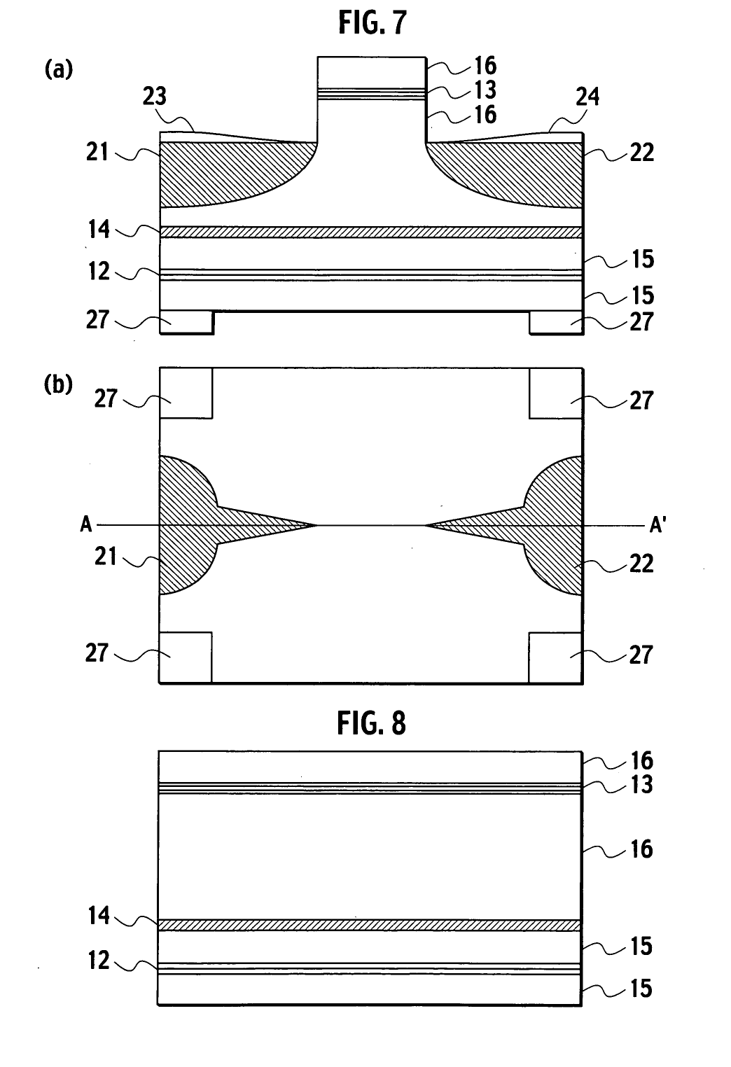

Furthermore, the semiconductor laser preferably further has lens electrodes for generating an electric field in at least part of the lower intrinsic semiconductor layer 15. An example of the present invention is shown in FIGS. 7(a) and 7(b). FIGS. 7(a) and 7(b) are views for explaining an example in which four lens electrodes are placed. FIG. 7(b) shows a situation in which lens electrodes 27 are placed at four corners of the bottom surface of the lower intrinsic semiconductor layer 15 shown in FIGS. 1(a) and 1(b). FIG. 7(a) is a view in which the cross section taken along the A-A′ line in FIG. 7(b) is seen from a side. As shown in FIG. 7(b), by forming the lens electrodes 27 at four corners of the semiconductor laser to generate an electric field, the movement of the positive holes and electrons can be limited, and the efficiency with which the positive holes and electrons are recombined to produce light can be also increased.

Incidentally, the number of lens electrodes 27 is not limited. The movement of the positive holes and electrons can be more finely limited by using lens electrodes in a plurality of directions. This method can be also applied to an electromagnet such as a dipole electromagnet or a quadrupole electromagnet. Further, the shapes of lens electrodes are also not limited. This makes it possible to increase the efficiency with which the positive holes and electrons are recombined to produce light. Accordingly, a semiconductor laser can be provided in which the emission efficiency can be further improved and in which the lasing threshold can be further lowered.

The distance between the upper and lower multiple reflection layers 13 and 12 is preferably not less than one wavelength no more than 30 wavelengths in terms of the lasing wavelength.

The lasing wavelength is a wavelength included in a broad waveband in which recombination occurs to produce light in the confining layer 14. The phase condition for lasing is made easy to satisfy by the distance between the upper and lower multiple reflection layers 13 and 12 being not less than one wavelength nor more than 30 wavelengths in terms of the wavelength of light produced by recombination in the confining layer 14. Further, the semiconductor laser can be made thin by the distance being not more than 30 wavelengths in terms of the wavelength of light produced by recombination in the confining layer 14. If the semiconductor laser is thin, heat dissipation is improved. Accordingly, stable lasing can occur even if a current is small. Thus, a semiconductor laser can be provided in which the emission efficiency can be further improved and in which the lasing threshold can be further lowered.

A method of manufacturing the semiconductor laser according to the present invention, which has been described using FIGS. 1(a) and 1(b), will be described using FIGS. 8 to 11(b). The semiconductor laser manufacturing method according to the present invention includes the steps of: depositing the lower intrinsic semiconductor layer 15 made of an intrinsic semiconductor which includes the lower multiple reflection layer 12 being made of intrinsic semiconductors and reflecting light to cause laser oscillation; forming the confining layer 14 on the lower intrinsic semiconductor layer 15 deposited in the step of depositing the lower intrinsic semiconductor layer, the confining layer confining the positive holes and electrons; depositing the upper intrinsic semiconductor layer 16 made of an intrinsic semiconductor on the confining layer 14 formed in the step of forming the confining layer, the upper intrinsic semiconductor layer 16 including the upper multiple reflection layer 13 being made of intrinsic semiconductors and reflecting light to cause laser oscillation; forming the electrode placement portions 17 by selectively removing, by dry etching, part of the upper intrinsic semiconductor layer 16 deposited in the step-of depositing the upper intrinsic semiconductor layer in accordance with shapes of the p-side electrode and the n-side electrode to be formed; placing the p-type electrode material 25 containing the acceptor impurities in one electrode placement portion 17 formed in the step of forming the electrode placement portions, and placing the n-type electrode material 26 containing the donor impurities in another electrode placement portion 17 formed in the step of forming the electrode placement portions; and annealing the p-type and n-type electrode materials 25 and 26 placed in the step of placing the p-type and n-type electrode materials, and at least part of the upper intrinsic semiconductor layer 16.

FIG. 8 is a view for explaining the step of depositing each of semiconductor layers on a substrate. On the substrate, Si which is the lower intrinsic semiconductor layer made of an intrinsic semiconductor is deposited. 10 pairs of GaAs and AlGaAs are deposited on the resultant structure to form the lower multiple reflection layer 12, and Si which is the lower intrinsic semiconductor layer 15 is deposited thereon. Then, the confining layer 14 is formed on the deposited lower intrinsic semiconductor layer 15. Then, Si which is the upper intrinsic semiconductor layer 16 is deposited on the confining layer 14, 10 pairs of GaAs and AlGaAs are deposited to form the upper multiple reflection layer 13, and Si which is the upper intrinsic semiconductor layer 16 is deposited on the resultant structure. Each of the semiconductor layers is deposited by metal-organic chemical vapor deposition (MOCVD).

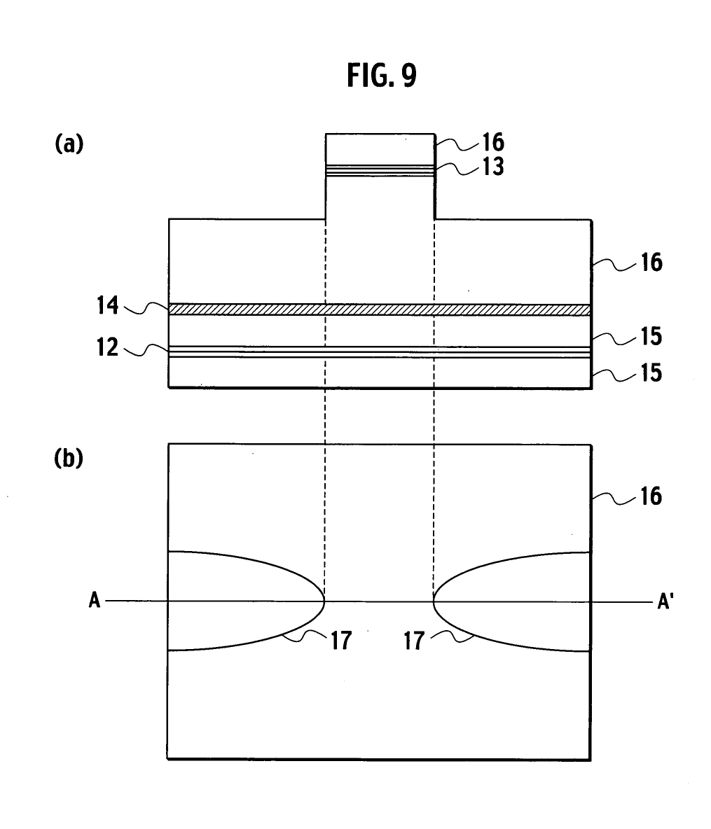

Next, the upper intrinsic semiconductor layer 16 deposited on the confining layer 14 is selectively removed by dry etching in accordance with the shapes of the p-side and n-side electrodes 23 and 24 to be formed. Thus, the electrode placement portions 17 are formed. FIG. 9(b) is a view for explaining etched shapes when the semiconductor laser is seen from the exit surface of laser light. FIG. 9(a) is a cross-sectional view taken along the A-A′ line in FIG. 9(b). As shown in FIG.(b), the upper intrinsic semiconductor layer 16 including the upper multiple reflection layer 13 is etched in convex shapes curved from both sides so that a center portion of the semiconductor laser is left. A resist mask is formed on the upper surface of the upper intrinsic semiconductor layer 16 by photolithography in accordance with the shapes shown in FIG. 9(b), and dry etching is performed using fluorine-based or chlorine-based halogen gas as an etchant. The etch depth is not limited, but the dry etching is stopped at a depth at which the confining layer 14 is not exposed.

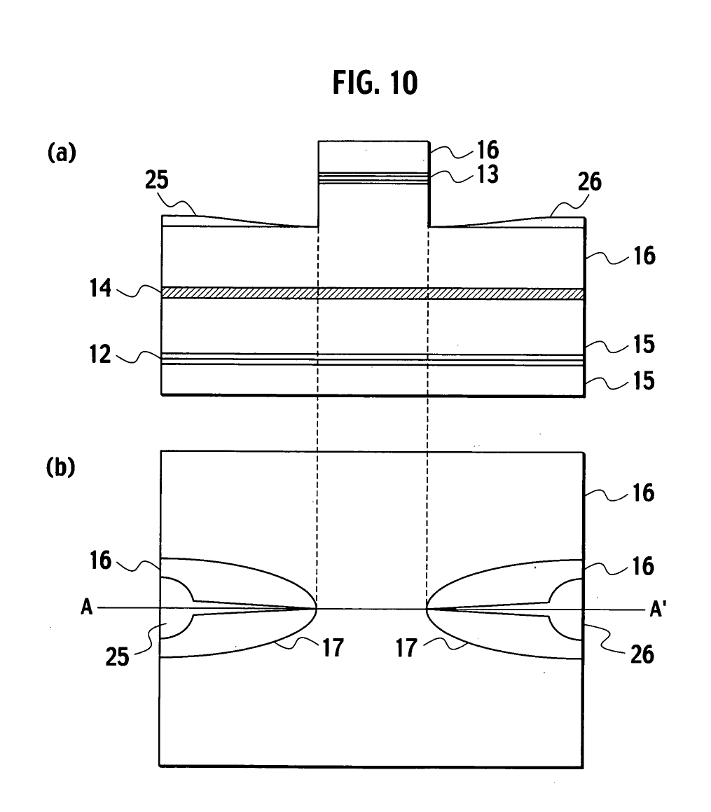

Next, an example in which p-type and n-type electrode materials 25 and 26 are formed is shown in FIGS. 10(a) and 10(b). FIG. 10(b) is a view for explaining the structure of the semiconductor laser as seen from the exit surface of laser light. FIG. 10(a) is a cross-sectional view taken along the A-A′ line in FIG. 10(b). As shown in FIGS. 10(a) and 10(b), the p-type and n-type electrode materials 25 and 26 are fixed to the electrode placement portions 17 formed by dry etching, respectively. Each of the shapes of the electrode materials to be fixed is a shape in which a columnar shape having semicircular bases with the centers thereof at a portion that becomes an end surface of the semiconductor laser is combined with a cone thinning toward the center of the semiconductor laser. The p-type and n-type electrode materials 25 and 26 face each other, and a gap is provided between the tips of the cone shapes provided therein so that lasing is not prevented.

Incidentally, Sn/Au and Zn/Au can be used as the p-type and n-type electrode materials 25 and 16, respectively. The p-type and n-type electrode materials 25 and 26 are fixed by forming a resist mask by photolithography, depositing the respective electrode materials on the upper intrinsic semiconductor layer 16, and performing lift-off.

As the p-type electrode material 25, a material to which acceptor impurities such as S, Se, or Te+Si are added may be used. Further, as the n-type electrode material 26, a material to which donor impurities such as Mg, C, Be, or B are added may be used.

Next, at least the p-type and n-type electrode materials 25 and 26 and the upper intrinsic semiconductor layer 16 are annealed. For example, the p-type and n-type electrode materials 25 and 26 and the upper intrinsic semiconductor layer 16 may be partially and selectively annealed by laser annealing. This annealing makes it possible to distribute the acceptor and donor impurities to the upper intrinsic semiconductor layer 16 from the p-type and n-type electrode materials 25 and 26, respectively.

An annealing method is not limited to this. For example, thermal annealing may be adopted in which heating is performed in an inert gas such as nitrogen or argon. For example, lamp annealing may be adopted. Annealing conditions may be selected depending on the material the crystal structure and the like of the p-type and n-type electrode materials 25 and 26, and the upper intrinsic semiconductor layer 16. For example, in the case where an intrinsic semiconductor having a zinc blende structure or a wurtzite structure is annealed, the acceptor and donor impurities added to the p-type and n-type electrode materials 25 and 26 can be distributed to the upper intrinsic semiconductor layer 16 by performing annealing at a temperature of approximately 150 degrees to 900 degrees for approximately one second to 100 hours.

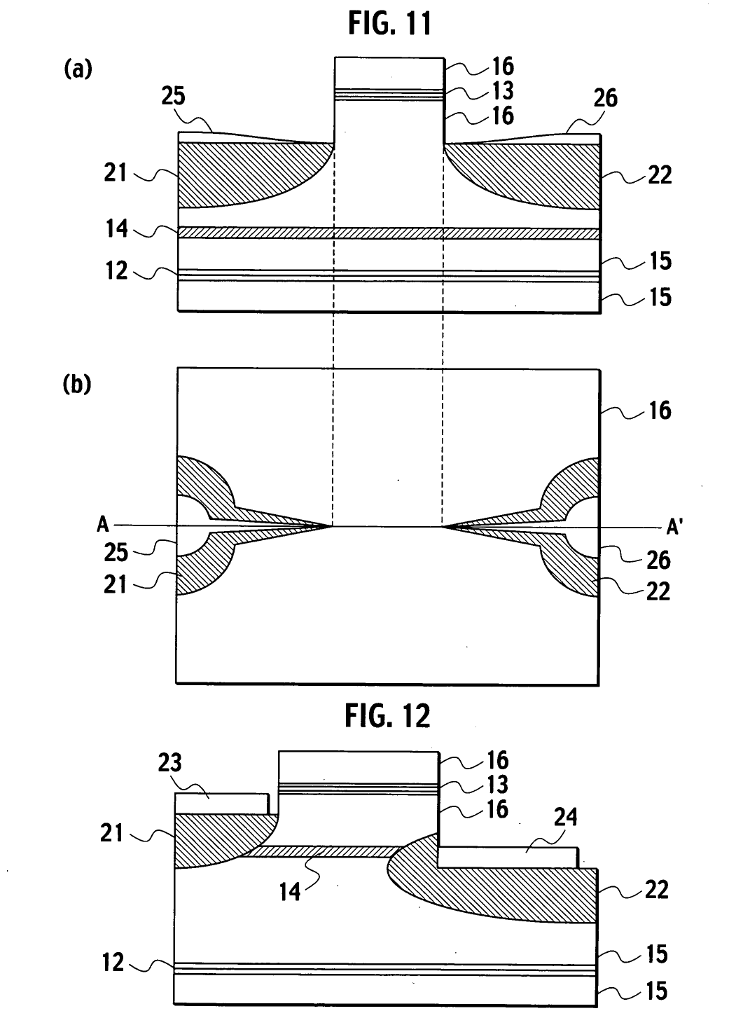

FIGS. 11(a) and 11(b) are views for explaining the states of the acceptor and donor impurities are distributed by annealing. FIG. 11(b) shows the projected shapes of the acceptor and donor impurities on the confining layer 14. FIG. 11(a) is a cross-sectional view taken along the A-A′ line in FIG. 11(b). In these drawings, “25” is the p-type electrode material, “26” is the n-type electrode material, “21” is the p-type semiconductor portion, and “22” is the n-type semiconductor portion. By performing annealing, the acceptor and donor impurities contained in the respective electrode materials can be distributed to the upper intrinsic semiconductor layer 16 as shown in FIGS. 11(a) and 11(b). This makes it possible to form the p-type and n-type semiconductor portions 21 and 22 so that current confinement is achieved in a center portion of the confining layer 14.

So far, a description has been given of a process for manufacturing the semiconductor laser according to the present invention which is shown in the aforementioned FIGS. 1(a) and 1(b). The above-described manufacturing process makes it possible to provide a semiconductor laser in which the emission efficiency can be improved and in which the lasing threshold can be lowered.

The semiconductor laser described in the above-described embodiment 1 may have the following constitution. Specifically, the semiconductor laser may include the following layers stacked in order: a GaAs substrate, a GaAs layer of 500 nm, a lower multiple reflection layer in which 38 pairs of Al_{0.95}GaAs reflection layers of 82.02 nm and GaAs reflection layers of 69.33 nm are stacked, an Al_{0.95}GaAs layer of 82.02 nm, a GaAs layer of 107.65 nm, a GaAs layer of 15 nm, an In_{0.2}GaAs layer of 75 nm, a GaAs layer of 10 nm, an In_{0.2}GaAs layer of 7.5 nm, a GaAs layer of 15 nm, a GaAs layer of 107.65 nm, and an upper multiple reflection layer in which 27 pairs of Al_{0.95}GaAs reflection layers of 82.02 nm and GaAs reflection layers of 69.33 nm are stacked. With such a structure, light having a wavelength of 980 nm can be lased.

### Embodiment 2

A semiconductor laser according to this embodiment will be described using FIG. 12. In this semiconductor laser, the p-type and n-type semiconductor portions 21 and 22 are placed so that the confining layer 14 is interposed between the highest portions of the density distributions of the acceptor and donor impurities of the p-type and n-type semiconductor portions 21 and 22. FIG. 12 is a view for explaining a cross-sectional structure of a semiconductor laser according to the present invention. FIG. 12 is almost the same as the aforementioned FIG. 1(a), but differs in the arrangement of the p-side electrode 23, the p-type semiconductor portion, the n-side electrode 24, and the n-type semiconductor portion 22. As in FIGS. 1(a) and 1(b), “12” is the lower multiple reflection layer, “13” is the upper multiple reflection layer, “15” is the lower intrinsic semiconductor layer, “16” is the upper intrinsic semiconductor layer, “14” is the confining layer, “21” is the p-type semiconductor portion, “22” is the n-type semiconductor portion, “23” is the p-side electrode, and “24” is the n-side electrode.

The upper intrinsic semiconductor layer 16, the upper multiple reflection layer 13, the confining layer 14, and the lower intrinsic semiconductor layer 15 are partially etched in accordance with the shape of the n-side electrode 24 at the position where the n-side electrode 24 is placed, and an electrode placement portion is thus formed. The n-side electrode 24 is formed on the lower intrinsic semiconductor layer 15 in which the electrode placement portion is formed. The n-side electrode 24 is placed in contact with the confining layer 14 exposed by etching. The n-type semiconductor portion 22 is formed with the n-side electrode 24 at an approximately central portion thereof so as to be distributed in the lower and upper intrinsic semiconductor layers 15 and 16.

On the other hand, the p-side electrode 23 is formed on the upper intrinsic semiconductor layer 16 etched to a depth which does not reach the confining layer 14. The p-type semiconductor portion 21 is distributed with the p-side electrode 23 at an approximately central portion thereof across the confining layer 14 in the upper intrinsic semiconductor layer 16 including the upper multiple reflection layer 13, and the lower intrinsic semiconductor layer 15.

The p-type and n-type semiconductor portions 21 and 22 do not overlap each other, and are placed to be separated in the stacking direction of the lower and upper intrinsic semiconductor layers 15 and 16 and in a direction perpendicular to the stacking direction. This makes it possible to lase light produced in the confining layer 14 without placing impurities, which absorb light, in the two multiple reflection layers, the lower and upper multiple reflection layers 12 and 13.

Also with the above-described constitution in which the confining layer 14 is placed between the p-type and n-type semiconductor portions 21 and 22, the reflectivity of the lower and upper multiple reflection layers can be prevented from being reduced by the acceptor and donor impurities, and the emission efficiency can be improved. Accordingly, a semiconductor laser can be provided in which the emission efficiency can be improved and in which the lasing threshold can be lowered.

It is preferable that at least one of the p-type and n-type semiconductor portions 21 and 22 is formed across the upper and lower intrinsic semiconductor layers 16 and 15. That is, it is preferable that any one of the acceptor impurities provided in the p-type semiconductor portion 21 and the donor impurities provided in the n-type semiconductor portion 22 is distributed across the upper and lower intrinsic semiconductor layers 16 and 15. Thus, the p-type semiconductor portion 21 and/or the n-type semiconductor portions 22 can efficiently supply the positive holes and/or electrons to the confining layer. Accordingly, a semiconductor laser can be provided in which the emission efficiency can be further improved and in which the lasing threshold can be further lowered.

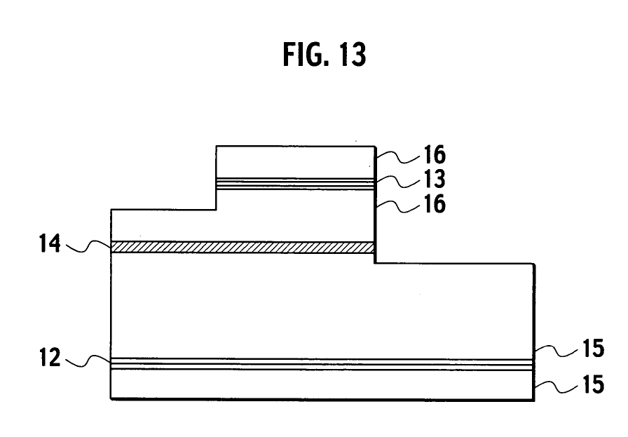

A method of manufacturing the semiconductor laser of this embodiment will be described using FIGS. 12 and 13. A semiconductor laser manufacturing method according to the present invention includes the steps of: depositing the lower intrinsic semiconductor layer 15 made of an intrinsic semiconductor which includes the lower multiple reflection layer 12 being made of intrinsic semiconductors and reflecting light to cause laser oscillation; forming the confining layer 14 on the lower intrinsic semiconductor layer 15 deposited in the step of depositing the lower intrinsic semiconductor layer, the confining layer 14 confining positive holes and electrons; depositing the upper intrinsic semiconductor layer 16 made of an intrinsic semiconductor on the confining layer 14 formed in the step of forming the confining layer, the upper intrinsic semiconductor layer 16 including the upper multiple reflection layer 13 being made of intrinsic semiconductors and reflecting light to cause laser oscillation; forming electrode placement portions by selectively removing, by dry etching, part of the lower intrinsic semiconductor layer 15 deposited in the step of depositing the lower intrinsic semiconductor layer, the confining layer 14 formed in the step of forming the confining layer, and the upper intrinsic semiconductor layer 16 deposited in the step of depositing the upper intrinsic semiconductor layer in accordance with a shape of any one of the p-side electrode 23 and the n-side electrode 24 to be formed, and by selectively removing, by dry etching, the upper intrinsic semiconductor layer 16 deposited in the step of depositing the upper intrinsic semiconductor layer in accordance with a shape of another of the p-side and n-side electrodes 23 an 24 to be formed; placing the p-type electrode material 25 containing the acceptor impurities in one electrode placement portion 17 formed in the step of forming the electrode placement portions, and placing the n-type electrode material 26 containing the donor impurities in other electrode placement portion 17 formed in the step of forming the electrode placement portions; and annealing the p-type and n-type electrode materials 25 and 26 placed in the step of placing the electrode materials, and at least part of the lower intrinsic semiconductor layer 15.

A process for manufacturing the semiconductor laser of this embodiment is almost the same as that of the embodiment 1 which has been described in FIGS. 8 to 11(b). The difference with the embodiment 1 is a removed depth by dry etching.

In this embodiment, in the step of selectively removing the upper intrinsic semiconductor layer 16 and the confining layer 14 by dry etching, dry etch depths for forming the electrode placement portions differ between the p-side and n-side electrodes 23 and 24.

FIG. 13 shows a cross-sectional structure of the semiconductor laser after dry etching. The electrode placement portion of the n-side electrode is formed by partially removing the upper intrinsic semiconductor layer 16 including the upper multiple reflection layer 13, the confining layer 14, and the lower intrinsic semiconductor layer 15 by dry etching. As for the lower intrinsic semiconductor layer 15, only a portion thereof which is close to the surface in contact with the confining layer 14 is removed. The n-side electrode 24 is formed on the lower intrinsic semiconductor layer 15 so as to be electrically connected to the confining layer 14. This makes it possible to directly supply a current from the n-side electrode 24 to the confining layer 14.

On the other hand, the electrode placement portion of the p-side electrode is formed by removing the upper intrinsic semiconductor layer 16 including the upper multiple reflection layer 13 to a depth which does not reach the confining layer 14 by dry etching. That is, the electrode placement portion of the p-side electrode is placed in the upper intrinsic semiconductor layer 16. Incidentally, the distance between the electrode placement portion of the p-side electrode and the confining layer 14 is not limited. The p-type and n-type electrode materials are fixed to the electrode placement portions of the p-side and n-side electrodes formed as described above, and the acceptor and donor impurities are thermally diffused by annealing to form the p-type and n-type semiconductor portions.

So far, a description has been given of a process for manufacturing the semiconductor laser according to the present invention which is shown in the aforementioned FIG. 12. The above-described manufacturing process makes it possible to prevent a current from flowing between the p-type and n-type semiconductor portions without flowing through the confining layer and to provide a semiconductor laser in which the emission efficiency can be improved and in which the lasing threshold can be lowered.

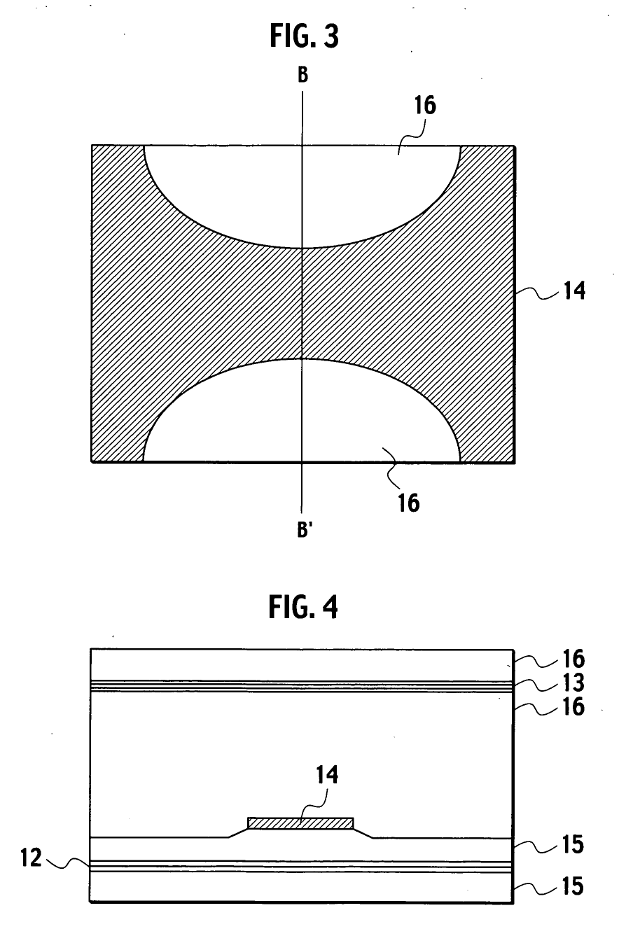

Incidentally, in the embodiments 1 and 2, the p-type semiconductor portion 21 and/or the n-type semiconductor portion 22 may be distributed from the corresponding electrode placement portions (or portion) 17 which supply currents to the p-type and n-type semiconductor portions 21 and 22, to a portion reaching the confining layer. 14. The structure of the semiconductor laser of this embodiment is shown in FIG. 2. FIG. 2 is a semiconductor laser almost the same as that shown in FIG. 1(a). The difference with that of FIG. 1(a) is a range in which the p-type and n-type semiconductor portions 21 and 22 are distributed. The p-type and n-type semiconductor portions 21 and 22 are widely distributed from the upper intrinsic semiconductor layer 16 placed on the confining layer 14 to the lower intrinsic semiconductor layer 15 placed under the confining layer 14, compared to those of FIG. 1. Thus, the p-type semiconductor portion 21 and/or the n-type semiconductor portion 22 can increase the efficiencies with which the positive holes and/or electrons are supplied to the confining layer 14. Accordingly, a semiconductor laser can be provided in which the emission efficiency can be further improved and in which the lasing threshold can be further lowered.

Moreover, in the embodiments 1 and 2, the distance between the p-type and n-type semiconductor portions 21 and 22 in a direction approximately perpendicular to the stacking direction is 2 μm, but not limited to this. Even if the distance is shorter than 2 μm, the lasing efficiency can be improved compared to those of known semiconductor lasers because acceptor and donor impurities enough to have conductivity are not contained in the lower and upper intrinsic semiconductor layers 15 and 16. Further, even if the distance is longer than 2 μm, light can be efficiently produced in the confining layer 14 by forming the confining layer 14 into a narrowed shape.

Moreover, the lower and upper multiple reflection layers 12 and 13 may be deposited at any positions in the lower and upper intrinsic semiconductor layers 15 and 16, respectively. The wavelength of amplified light can be changed by changing the distance between the lower and upper multiple reflection layers 12 and 13 between which the confining layer 14 is interposed.

The distances between the confining layer 14 and the electrode placement portions 17 are not limited. If the distances between the confining layer 14 and the electrode placement portions 17 are not more than 200 nm, the efficiency with which the tunnel effect occurs between the confining layer 14 and the respective electrodes formed in the electrode placement portions 17 becomes high. Accordingly, the efficiency with which the positive holes and electrons are supplied from the p-type and n-type semiconductor portions 21 and 22 to the confining layer can be improved.

Further, in the aforementioned embodiments, GaAs/AlGaAs materials are used for the lower and upper multiple reflection layers 12 and 13, but the materials thereof are not limited to these. It is possible to use AlGaN, AlGaInP/GaAs, InAlAs/InGaAs, or InP/InGaAlAs materials, or the like.

Further, the upper multiple reflection layer 13 may be a dielectric material. For example, the dielectric materials include SiO₂/TiO₂, ZrO/SiO₂, and MgO/SiO₂ materials. By using such materials, an upper multiple reflection layer, which absorbs little light, can be formed.

Further, the number of pairs of the lower and upper multiple reflection layers 12 and 13 is not limited. Since they may not contain the acceptor and donor impurities, the number of pairs constituting each of the lower and upper multiple reflection layers 12 and 13 can be increased. Although there are 10 pairs in the aforementioned embodiment, there may be 20 pairs or 30 pairs. Increasing the number of pairs further improves the reflectivity of the lower and upper multiple reflection layers 12 and 13, and makes it possible to improve the emission efficiency.

Further, the upper and lower intrinsic semiconductor layers 16 and 15 are not limited to intrinsic semiconductors in which atoms can share electrons in the outermost shells thereof.

The group III-V or II-VI semiconductors in which the densities of the acceptor and donor impurities are not more than one-tenth of those of the p-type and n-type semiconductor portions 21 and 22 may be adopted. That is, in the case where the densities of the acceptor and donor impurities are 10 raised to the 18th power, the group III-V or II-VI semiconductors having carrier densities not more than 10 raised to the 16th power are acceptable. The group III-V semiconductors include, for example, GaN, GaAs, and InP. Semiconductors including at least one of the group III elements, which are B, Al, Ga, In, and Tl, and at least one of group V elements, which are N, P, As, Sb, and Bi. The group II-VI semiconductors include, for example, ZnO, ZnS, ZnSe, ZnTe, CdS, CdSe, CdTe, BeSe, BeTe, MgS, MgSe, and MgTe.

The upper and lower intrinsic semiconductor layers 16 and 15 may be formed using the same materials as those of the lower and upper multiple reflection layers 12 and 13. That is, it is also possible to use AlGaAs/GaAs, AlGaN, AlGaInP/GaAs, InAlAs/InGaAs, or InP/InGaAlAs semiconductors. Further, dielectric materials such as SiO₂/TiO₂, ZrO/SiO₂, or MgO/SiO₂ materials are acceptable.

Further, a description has been given for the case where MOCVD is used as an epitaxy growth method. However, an epitaxy growth method is not limited to this. For example, molecular beam epitaxy (MBE), liquid phase epitaxy (LPE), or the like may be used.

Further, the shapes of the p-type and n-type electrode materials to be fixed are not limited. They may be placed in stick-like shapes extending from the end surfaces of the semiconductor laser to the center, or may have comb-like shapes to provide current confinement at a plurality of positions.

Further, a method of fixing the p-type and n-type electrode materials is not limited. For example, chemical vapor deposition (CVD), vapor deposition, or sputtering may be adopted. They can be also fixed by forming metal films by vapor deposition.

Further, the p-side and n-side electrodes and the lens electrodes are not limited to Au/Ti. Materials including Pt/Ti alloys and Au alloys, such as used in compound semiconductor processes, may be used.

The semiconductor laser of the present invention can be applied to a light source, a luminaire, or an optical integrated circuit used in an optical communication device, a sensor, or the like. Further, since the semiconductor laser can be constituted so as to have a stacked structure including a confining layer and intrinsic semiconductor layers, heat generated in laser oscillation is easily released to the outside. Thus, it is also possible to provide a semiconductor laser in which cracks are less prone to appear.

In the semiconductor laser according to the present invention, the p-type and n-type semiconductor portions are placed to positions where they can sufficiently supply the positive holes and electrons to the confining layer. Accordingly, the positive holes and electrons can be supplied to the confining layer from the p-type and n-type semiconductor portions, respectively. This makes it possible to recombine the positive holes and electrons in the confining layer to produce light.

In the semiconductor laser according to the present invention, lasing portions on opposite sides of the confining layer requires the conductivities which are sufficiently lower than those of the p-type and n-type semiconductor portions. Accordingly, the lasing portions can be made of intrinsic semiconductors. Light produced in the confining layer is reflected by the multiple reflection layers respectively provided in the upper and lower intrinsic semiconductor layers between which the confining layer is interposed.

In the semiconductor laser according to the present invention, the intrinsic semiconductor layers, including the multiple reflection layers, may not contain either acceptor impurities or donor impurities because the intrinsic semiconductor layers do not need to have conductivity. Layers provided between the multiple reflection layers are the intrinsic semiconductor layers and the confining layer. Accordingly, in the semiconductor laser according to the present invention, lasing can occur in a space which does not contain many acceptor and donor impurities that absorb light to cause a reduction of the emission efficiency. This makes it possible to prevent the reflectivity of the multiple reflection layers from being reduced by the acceptor and donor impurities and to improve the emission efficiency.

The constitution of the semiconductor laser according to the present invention makes it possible to cause laser oscillation without placing impurities, which absorb light, in the upper and lower multiple reflection layers, which are two multiple reflection layers placed with the confining layer interposed therebetween. Accordingly, a semiconductor laser can be provided in which the emission efficiency can be improved and in which the lasing threshold can be lowered.

In the semiconductor laser according to the present invention, the p-type and n-type semiconductor portions may be formed at positions where they do not prevent light produced in the confining layer from lasing. This makes it possible to prevent lasing light from being absorbed by the acceptor and donor impurities. Accordingly, a semiconductor laser can be provided in which the emission efficiency can be further improved and in which the lasing threshold can be further lowered.

In the semiconductor laser according to the present invention, adjacent portions of the density distributions of the acceptor and donor impurities respectively provided in the p-type and n-type semiconductor portions may have shapes with which current confinement is achieved in the confining layer. This makes it possible to efficiently cause recombination radiation in the confining layer. Accordingly, a semiconductor laser can be provided in which the emission efficiency can be further improved and in which the lasing threshold can be further lowered.

In the semiconductor laser according to the present invention, in adjacent portions of the density distributions of the acceptor and donor impurities respectively provided in the p-type and n-type semiconductor portions, the projected shapes of the p-type and n-type semiconductor portions on the confining layer may have convex shapes having vertices in portions thereof which are closest to each other. Thus, the p-type and n-type semiconductor portions can provide current confinement in the confining layer. Accordingly, a semiconductor laser can be provided in which the emission efficiency can be further improved and in which the lasing threshold can be further lowered.

In the semiconductor laser according to the present invention, the density distributions of the acceptor and donor impurities respectively provided in the p-type and n-type semiconductor portions may be formed to face each other in a direction approximately perpendicular to the stacking direction of the lower and upper intrinsic semiconductor layers. This makes it possible to place the p-side and n-side electrodes in the same layer. Accordingly, a semiconductor laser can be provided which is easily manufactured, in which the emission efficiency can be improved, and in which the lasing threshold can be lowered.

In the semiconductor laser according to the present invention, by placing the p-side and n-side electrodes on opposite sides of the confining layer, a current can be prevented from flowing between the p-type and n-type semiconductor portions without flowing through the confining layer. Accordingly, a semiconductor laser can be provided in which the emission efficiency can be improved and in which the lasing threshold can be lowered.

In the semiconductor laser according to the present invention, the acceptor and donor impurities provided in the p-type and n-type semiconductor portions may be closely placed at a distance at which the tunnel effect occurs. Since the distributions of the acceptor and donor impurities can be prevented from widening, it is possible to prevent impurities from being distributed in the intrinsic semiconductor portions. Accordingly, a semiconductor laser can be provided in which the emission efficiency can be improved and in which the lasing threshold can be lowered.

In the semiconductor laser according to the present invention, the acceptor and donor impurities provided in the p-type and n-type semiconductor portions may be placed close to the confining layer at a distance of not more than 200 nm therefrom. This makes it possible to prevent the distributions of the acceptor and donor impurities from widening, and therefore makes it possible to prevent impurities from being distributed in the intrinsic semiconductor portions. Accordingly, a semiconductor laser can be provided in which the emission efficiency can be improved and in which the lasing threshold can be lowered.

The semiconductor laser according to the present invention may have either one or both of the following features: the acceptor impurities provided in the p-type semiconductor portion are distributed from the p-side electrode to the confining layer; and the donor impurities provided in the n-type semiconductor portion are distributed from the n-side electrode to the confining layer. Thus, the p-type semiconductor portion and/or the n-type semiconductor portion can efficiently supply the positive holes and/or electrons to the confining layer. Accordingly, a semiconductor laser can be provided in which the emission efficiency can be further improved and in which the lasing threshold can be further lowered.

In the semiconductor laser according to the present invention, at least any one of the acceptor and donor impurities respectively provided in the p-type and n-type semiconductor portions may be distributed across the upper and lower intrinsic semiconductor layers. Thus, the p-type semiconductor portion and/or the n-type semiconductor portion can efficiently supply the positive holes and/or electrons to the confining layer. Accordingly, a semiconductor laser can be provided in which the emission efficiency can be further improved and in which the lasing threshold can be further lowered.

In the semiconductor laser according to the present invention, the confining layer and layers between which the confining layer is interposed may constitute a double-hetero structure. This makes it possible to efficiently confine the positive holes and electrons in the confining layer. Accordingly, a semiconductor laser can be provided in which the emission efficiency can be improved and in which the lasing threshold can be lowered.

In the semiconductor laser according to the present invention, the effect of confining the positive holes and electrons in the confining layer can be improved by the confining layer including a quantum well structure. Accordingly, a semiconductor laser can be provided in which the emission efficiency can be further improved and in which the lasing threshold can be further lowered.

Thus, in the semiconductor laser according to the present invention, a portion, in which the positive holes and electrons can exist, can be narrowed by the confining layer having a narrowed shape. Accordingly, the efficiency with which the positive holes and electrons are recombined to produce light can be improved. Accordingly, a semiconductor laser can be provided in which the emission efficiency can be further improved and in which the lasing threshold can be further lowered.

The semiconductor laser according to the present invention may have a structure in which the confining layer is processed to have a striped shape and in which the surrounding region is filled with a high-resistance semiconductor crystal. This makes it possible to narrow a portion in which the positive holes and electrons recombine. Thus, the positive holes and electrons can be efficiently recombined to produce light. Accordingly, a semiconductor laser can be provided in which the emission efficiency can be further improved and in which the lasing threshold can be further lowered.

In the semiconductor laser according to the present invention, the movement of the positive holes and electrons in the confining layer can be limited by an electric field generated by lens electrodes. This can improve the efficiency with which the positive holes and electrons are recombined to produce light. Accordingly, a semiconductor laser can be provided in which the emission efficiency can be further improved and in which the lasing threshold can be further lowered.

In the semiconductor laser according to the present invention, the lasing efficiency can be improved by providing at least 10 pairs of reflection layers constituting each of the upper and lower multiple reflection layers. Accordingly, a semiconductor laser can be provided in which the emission efficiency can be further improved and in which the lasing threshold can be further lowered.

In the semiconductor laser according to the present invention, the reflectance of light produced in the confining layer can be increased by forming the reflection layers of AlGaAs, AlGaN, AlGaInN, AlGaInAs, ZnCdSeS, ZnMgSSe, or ZnSSe materials. Accordingly, a semiconductor laser can be provided in which the emission efficiency can be further improved and in which the lasing threshold can be further lowered.

In the semiconductor laser according to the present invention, the lasing wavelength is a wavelength included among wavelengths of light produced by recombination in the confining layer. The phase condition for lasing is made easy to satisfy by the distance between the upper and lower multiple reflection layers being not less than one wavelength nor more than 30 wavelengths in terms of the wavelength of light produced by recombination in the confining layer. Further, the semiconductor laser can be made thin by the distance being not more than 30 wavelengths in terms of the wavelength of light produced by recombination in the confining layer. If the semiconductor laser is thin, heat dissipation is improved. Accordingly, stable lasing can occur even if a current is small. Thus, a semiconductor laser can be provided in which the emission efficiency can be further improved and in which the lasing threshold can be further lowered. Incidentally, one wavelength here means a wavelength in each semiconductor layer provided between the upper and lower multiple reflection layers. The wavelength in each semiconductor layer is calculated by dividing a wavelength in a vacuum by the refractive index of the semiconductor layer.

In the semiconductor laser manufacturing method according to the present invention, the p-type and n-type semiconductor portions can be formed by thermally diffusing the acceptor and donor impurities to the intrinsic semiconductor layers by annealing. The semiconductor laser manufacturing method according to the present invention makes it possible to manufacture the semiconductor laser according to the present invention. Incidentally, the semiconductor laser manufacturing method according to the present invention is particularly effective in the case where the density distributions of the p-type and n-type semiconductor portions are formed to face each other in a direction approximately perpendicular to the stacking direction of the intrinsic semiconductor layers. Accordingly, a semiconductor laser can be provided in which the emission efficiency can be improved and in which the lasing threshold can be lowered.

As described previously, in the semiconductor laser manufacturing method according to the present invention, the p-type and n-type semiconductor portions can be formed by thermally diffusing the acceptor and donor impurities to the intrinsic semiconductor layers by annealing. The semiconductor laser manufacturing method according to the present invention makes it possible to manufacture the semiconductor laser according to the present invention. Incidentally, in particular, the semiconductor laser manufacturing method according to the present invention can prevent a current from flowing between the p-type and n-type semiconductor portions without flowing through the confining layer. Accordingly, a semiconductor laser can be provided in which the emission efficiency can be improved and in which the lasing threshold can be lowered.

According to the present invention, by allowing laser oscillation in the stacking direction without providing the acceptor and donor impurities in the multiples reflection layers, a semiconductor laser can be provided in which the emission efficiency can be improved and in which the lasing threshold can be lowered.

Additional advantages and modifications will readily occur to those skilled in the art. Therefore, the invention in its broader aspects is not limited to the specific details and the representative embodiments shown and described herein. Accordingly, various modifications may be made without departing from the scope of the general inventive concept as defined by the appended claims and their equivalents.

What is claimed is:

1. A semiconductor laser comprising:
a confining layer configured to confine positive holes and electrons;
an upper intrinsic semiconductor layer made of an intrinsic semiconductor which is placed on one side of the confining layer in a stacking direction;
an upper multiple reflection layer made of intrinsic semiconductors which are placed in a portion of the upper intrinsic semiconductor layer in parallel with a plane of the confining layer and is configured to reflect part of light produced in the confining layer to cause laser oscillation;
a lower intrinsic semiconductor layer made of an intrinsic semiconductor which is placed on another side of the confining layer in the stacking direction;
a lower multiple reflection layer made of intrinsic semiconductors which are placed in a portion of the lower intrinsic semiconductor layer in parallel with the plane of the confining layer and is configured to reflect part of light produced in the confining layer to cause laser oscillation;
a p-type semiconductor portion formed by distributing acceptor impurities in a portion of the upper intrinsic semiconductor layer and/or the lower intrinsic semiconductor layer; and
an n-type semiconductor portion placed to be separated from the p-type semiconductor portion in a direction perpendicular to a stacking direction of the upper and lower intrinsic semiconductor layers, the n-type semiconductor portion being formed by distributing donor impurities in a portion of the upper intrinsic semiconductor layer and/or the lower intrinsic semiconductor layer,
wherein positive holes supplied from the p-type semiconductor portion and electrons supplied from the n-type semiconductor portion recombine in the confining layer to produce light.

2. The semiconductor laser according to claim 1, wherein the p-type and n-type semiconductor portions are placed at positions where the p-type and n-type semiconductor portions do not prevent the light produced in the confining layer from being emitted by laser oscillation in the stacking direction of the upper and lower intrinsic semiconductor layer.

3. The semiconductor laser according to claim 1, wherein adjacent portions of the p-type and n-type semiconductor portions have shapes with which current confinement is achieved in the confining layer.

4. The semiconductor laser according to claim 1, wherein projected shapes of adjacent portions of the p-type and n-type semiconductor portions on the confining layer have convex shapes having vertices in the adjacent portions.

5. The semiconductor laser according to claim 1, wherein the p-type and n-type semiconductor portions are formed in any one of the upper and lower intrinsic semiconductor layers to face each other in a direction approximately perpendicular to the stacking direction of the upper and lower intrinsic semiconductor layers.

6. The semiconductor laser according to claim 1, wherein the p-type and n-type semiconductor portions are placed so that the highest portions of density distributions of the acceptor and donor impurities of the p-type and n-type semiconductor portions are placed with the confining layer interposed therebetween.

7. The semiconductor laser according to claim 1, wherein the p-type semiconductor portion and/or the n-type semiconductor portion is formed from at least one of electrode placement portions from which currents are respectively supplied to the p-type and n-type semiconductor portions, to a portion in which the positive holes and electrons cause the tunnel effect to the confining layer.

8. The semiconductor laser according to claim 1, wherein the p-type semiconductor portion and/or the n-type semiconductor portion is formed from at least one of electrode placement portions from which currents are respectively supplied to the p-type and n-type semiconductor portions, to a portion at a distance of not more than 200 nm from the confining layer.

9. The semiconductor laser according to claim 1, wherein the p-type semiconductor portion and/or the n-type semiconductor portion is distributed from at least one of electrode placement portions from which currents are respectively supplied to the p-type and n-type semiconductor portions, to a portion reaching the confining layer.

10. The semiconductor laser according to claim 1, wherein at least one of the p-type and n-type semiconductor portions is formed across the upper and lower intrinsic semiconductor layers.

11. The semiconductor laser according to claim 1, wherein the confining layer has a double-hetero structure interposed between layers having large energy gaps.

12. The semiconductor laser according to claim 1, wherein the confining layer has a quantum well structure.

13. The semiconductor laser according to claim 1, wherein the confining layer has a narrowed shape in at least part of a portion which connects projected portions of the p-type and n-type semiconductor portions on the confining layer.

14. The semiconductor laser according to claim 1, wherein the confining layer has a stripe structure which connects adjacent portions of projected portions of the p-type and n-type semiconductor portions on the confining layer, in at least the adjacent portions.

15. The semiconductor laser according to claim 1, further comprising: a lens electrode in a portion close to at least part of the upper intrinsic semiconductor layer and/or the lower intrinsic semiconductor layer, the lens electrode limiting movement of the positive holes and electrons using an electric field.

16. The semiconductor laser according to claim 1, wherein each of the upper and lower multiple reflection layers has at least 10 pairs of reflection layers.

17. The semiconductor laser according to claim 1, wherein the upper and lower multiple reflection layers are formed of any one of AlGaAs, AlGaN, AlGaInN, AlGaInAs, ZnCdSeS, ZnMgSSe, and ZnSSe materials.

18. The semiconductor laser according to claim 1, wherein a distance between the upper and lower multiple reflection layers is in a range from one wavelength to 30 wavelengths in terms of a lasing wavelength.

19. A method of manufacturing a semiconductor laser, comprising:
depositing a lower intrinsic semiconductor layer made of an intrinsic semiconductor which includes a lower multiple reflection layer being made of intrinsic semiconductors and reflecting light to cause laser oscillation;
forming a confining layer on the lower intrinsic semiconductor layer deposited in the step of depositing the lower intrinsic semiconductor layer, the confining layer confining positive holes and electrons;
depositing an upper intrinsic semiconductor layer made of an intrinsic semiconductor on the confining layer formed in the step of forming the confining layer, the upper intrinsic semiconductor layer including an upper multiple reflection layer being made of intrinsic semiconductors and reflecting light to cause laser oscillation;
forming electrode placement portions by selectively removing, by dry etching, part of the upper intrinsic semiconductor layer deposited in the step of depositing the upper intrinsic semiconductor layer in accordance with shapes of a p-side electrode and an n-side electrode to be formed;
placing a p-type electrode material containing acceptor impurities in one electrode placement portion formed in the step of forming the electrode placement portions, and placing an n-type electrode material containing donor impurities in another electrode placement portion formed in the step of forming the electrode placement portions; and
annealing the p-type and n-type electrode materials placed in the step of placing the p-type and n-type electrode materials, and at least part of the upper intrinsic semiconductor layer.

20. A method of manufacturing a semiconductor laser, comprising:
depositing a lower intrinsic semiconductor layer made of an intrinsic semiconductor which includes a lower multiple reflection layer being made of intrinsic semiconductors and reflecting light to cause laser oscillation;
forming a confining layer on the lower intrinsic semiconductor layer deposited in the step of depositing the lower intrinsic semiconductor layer, the confining layer confining positive holes and electrons;
depositing an upper intrinsic semiconductor layer made of an intrinsic semiconductor on the confining layer formed in the step of forming the confining layer, the upper intrinsic semiconductor layer including an upper multiple reflection layer being made of intrinsic semiconductors and reflecting light to cause laser oscillation;
forming electrode placement portions by selectively removing, by dry etching, part of the lower intrinsic semiconductor layer deposited in the step of depositing the lower intrinsic semiconductor layer, the confining layer formed in the step of forming the confining layer, and the upper intrinsic semiconductor layer deposited in the step of depositing the upper intrinsic semiconductor layer in accordance with a shape of any one of a p-side electrode and an n-side electrode to be formed, and by selectively removing, by dry etching, the upper intrinsic semiconductor layer deposited in the step of depositing the upper intrinsic semiconductor layer in accordance with a shape of another of the p-side and n-side electrodes to be formed;
placing a p-type electrode material containing acceptor impurities in one electrode placement portion formed in the step of forming the electrode placement portions, and placing an n-type electrode material containing donor impurities in other electrode placement portion formed in the step of forming the electrode placement portions; and
annealing the p-type and n-type electrode materials placed in the step of placing the electrode materials, and at least part of the lower intrinsic semiconductor layer.
